(19) United States
(12) Patent Application Publication
(10) Pub. No.: US 2026/0229284 A1
(43) Pub. Date: Aug. 6, 2026

(54) RING OSCILLATOR STRUCTURE TO MONITOR WRITABILITY OF MULTI-PORT BITCELL

(71) Applicant: NVIDIA Corporation, Santa Clara, CA (US)

(72) Inventors: Manish Umedlal Patel, Bangalore (IN); Karthik Balakrishnan, Bangalore (IN)

(21) Appl. No.: 19/045,453

(22) Filed: Feb. 4, 2025

(51) Int. Cl. G11C 11/419; G06F 30/36

(52) U.S. Cl. CPC G11C 11/419; G06F 30/36

(57) ABSTRACT

A writability monitoring circuit in a static RAM (SRAM) of an integrated circuit (IC) is disclosed. In one embodiment, the writability monitoring circuit comprises a register, an array of multi-port test bitcell configured as a ring oscillator, and control circuitry. The control circuitry is configured to apply a voltage to the array of multi-port test bitcells and determine if the ring oscillator is oscillating. In one embodiment, the control circuitry is configured to adjust the voltage applied to the array of multi-port test bitcells when the ring oscillator is determined to be oscillating and is configured to determine a correlating minimum write voltage to successfully write to the array of multi-port test bitcells corresponding to a writability of the array of multi-port test bitcells when the ring oscillator is determined to not be oscillating and then send the correlated minimum write voltage to the register.

### TECHNICAL FIELD

This application is directed, in general, to on-chip multiport static RAMs (SRAMs) and, more specifically, to circuitry and a method to monitor writability of multi-port bitcells in the SRAM.

### BACKGROUND

Bitcell writability is of concern to integrated circuit designers. Bitcell writability is a measure of how easily a bitcell (typically of a multi-port static RAM (SRAM) in an IC) can be written. One measure of bitcell writability is what minimum voltage level is needed to successfully write data to a bitcell, e.g., of a multi-port SRAM. In some applications, if a bitcell can successfully have data written to it a 0.5V, the bitcell is considered to have good writability. In some applications, if a bitcell needs data to be written to it at 0.65V, the bitcell is considered to have poor writability.

For most IC designs, IC designers simulate their IC design using conventional simulation packages, e.g., Simulation Program with Integrated Circuit Emphasis (SPICE™). SPICE models rely on characterization of silicon electrical performance. However, if accurate silicon electrical performance for silicon from a silicon wafer manufacturer (including silicon wafer fabrication foundries) is not available or is not accurately known, IC designers cannot simulate their IC designs with a high level of confidence and will, as a result, have to conservatively design their ICs which causes, e.g., inefficient circuit design and layout of the IC and/or non-optimal electrical performance (e.g., speed, power, etc.).

In order to be able to accurately characterize electrical performance of silicon without available or accurate models (e.g., SPICE models) of the silicon, techniques to accurately model silicon electrical performance exist in the art. For example, implementation of built-in self-test (BIST) circuitry can be added to the IC design. In other examples, custom circuitry can be added to the IC design. However, in these and all other examples in the art, there is a penalty for this additional circuitry including: 1) the amount of time it takes to perform BIST (multiple read/writes at differing voltages must be performed); 2) additional silicon area that could/should be used for active circuitry; 3) increased power consumption; 4) timing concerns, etc.

### SUMMARY OF THE DISCLOSURE

In one aspect, a writability monitoring circuit in a static RAM (SRAM) of an integrated circuit (IC) is disclosed. In one embodiment, the writability monitoring circuit comprises a register, an array of multi-port test bitcell configured as a ring oscillator, and control circuitry. The control circuitry is configured to apply a voltage to the array of multi-port test bitcells and determine if the ring oscillator is oscillating. In one embodiment, the control circuitry is configured to adjust the voltage applied to the array of multi-port test bitcells when the ring oscillator is determined to be oscillating and is configured to determine a correlating minimum write voltage to successfully write to the array of multi-port test bitcells corresponding to a writability of the array of multi-port test bitcells when the ring oscillator is determined to not be oscillating and then send the correlated minimum write voltage to the register.

In another aspect, a method of determining writability of multi-port test bitcells in an SRAM of an IC is disclosed. In one embodiment, the method comprises initiating a ring oscillator from an array of the multi-port test bitcells in the SRAM and monitoring oscillations of the ring oscillator for a voltage applied to the array of multi-port test bitcells. When the ring oscillator is determined to be oscillating, the method further comprises adjusting the voltage applied to the array of multi-port test bitcells. And when the ring oscillator is determined to not be oscillating, the method further comprises determining a correlating minimum write voltage to successfully write to the array of multi-port test bitcells and sending the correlated minimum write voltage to a register of the SRAM.

In still another aspect, an SRAM of an IC is disclosed. In one embodiment, the SRAM comprises an array of multi-port bitcells, write drivers for the array of multi-port bitcells, a decoder for the array of multi-port bitcells, control logic for the array of multi-port bitcells, and a writability monitoring circuit. In one embodiment, the writability monitoring circuit comprises a register, and array of multi-port test bitcells, and control circuitry. In one embodiment, the control circuitry is configured to apply a voltage to the array of multi-port test bitcells and determine if the ring oscillator is oscillating. When the control circuitry determines the ring oscillator is oscillating, the control circuitry is further configured to adjust the voltage applied to the array of multi-port test bitcells. And when the control circuitry determines the ring oscillator is not oscillating, the control circuitry is further configured to determine a correlating minimum write voltage to successfully write to the array of multi-port test bitcells and send the correlated minimum write voltage to the register.

In yet another aspect, a library of circuit designs is disclosed. In one embodiment, the library of circuit designs comprises a design for a writability monitoring circuit in an SRAM of an IC is disclosed where, in one embodiment, the writability monitoring circuit includes a register, an array of multi-port test bitcells configured as a ring oscillator, and control circuitry. In one embodiment, the control circuitry is configured to apply a voltage to the array of multi-port test bitcells and determine if the ring oscillator is oscillating. In one embodiment, when the control circuitry determines the ring oscillator is oscillating, the control circuitry is further configured to adjust the voltage applied to the array of multi-port test bitcells. And when the control circuitry determines the ring oscillator is not oscillating, the control circuitry is further configured to determine a correlating minimum write voltage to successfully write to the array of multi-port test bitcells and send the correlated minimum write voltage to the register.

In still yet another aspect, a writability monitoring circuit in an SRAM of an IC is disclosed. In one embodiment, the writability monitoring circuit comprises a register, an array of test bitcells configured as a ring oscillator, and control circuitry configured to determine a correlating minimum write voltage to successfully write to the array of test bitcells and send the correlated minimum write voltage to the register.

### BRIEF DESCRIPTION OF THE DRAWINGS

Reference is now made to the following descriptions taken in conjunction with the accompanying drawings, in which:

FIG. 1 illustrates a block diagram of an example of an integrated circuit (IC) according to principles of the disclosure;

FIG. 2 illustrates a block diagram of an example of a static RAM (SRAM) according to principles of the disclosure;

FIG. 3 illustrates a block diagram of an example of a writability monitor according to principles of the disclosure;

FIG. 4 illustrates a schematic of an example of a representative multi-port (2 port) bitcell;

FIG. 5 illustrates a block diagram of an example of a 4×1 two-port test bitcell array configured as a ring oscillator according to principles of the disclosure;

FIG. 6 illustrates a block diagram of an example of a 4×1 four-port test bitcell array configured as a ring oscillator according to principles of the disclosure;

FIG. 7 illustrates a block diagram of an example of a 4×3 two-port test bitcell array with control circuitry according to principles of the disclosure; and

FIG. 8 illustrates a flow diagram of an example of a method of determining writability and write time of multi-port test bitcells in an SRAM of an IC according to principles of the disclosure.

### DETAILED DESCRIPTION OF THE DISCLOSURE

As discussed above, there are many drawbacks to existing techniques to be able to accurately predict electrical performance of silicon so that bitcell writability can be determined. This disclosure provides circuitry and a method to accurately determine bitcell writability that overcomes the above-noted problems with existing techniques. The disclosed circuitry and method also accurately determines a write time of the bitcell. The disclosed circuitry and method utilizes a ring oscillator that takes a very, very small silicon area and consumes very, very low power without compromising IC timing to determine bitcell writability and write-time of the bitcell.

In addition to being able to accurately predict electrical performance of silicon, the disclosed circuitry and method can also be used as an input to control parameters of the IC. For example, if the disclosed monitoring indicates good writability to bitcells of the SRAM (i.e., successfully writing to the bitcell with lower voltages, e.g., 0.5V), then this indication can be fed back into the IC to control other parameters of the IC in which the test bitcells reside. For example, if the voltage needed to successfully write to the bitcell is lower (i.e., good writability as defined above) then, e.g., the overall operating voltage for the IC can be manipulated to be lowered, thereby saving power consumption of the IC, improving the speed at which the IC operates, or both.

The writability of the multi-port SRAM bitcell is directly proportional to various voltages applied to the bitcell. For example, the voltage applied to a write wordline of the SRAM is directly proportional to the amount of voltage needed to successfully write to the bitcell of the SRAM. Alternatively, the overall supply voltage of the SRAM, e.g., V_{DD}, is proportional to the amount of voltage needed to successfully write to the bitcell of the SRAM. Further, the voltage applied to a write bitline of the SRAM is also proportional to the amount of voltage needed to successfully write to the bitcell of the SRAM. Thus, for the writability of the bitcell of the SRAM to be monitored, the voltage required to successfully write to the bitcell correlates to the write wordline voltage (or to V_{DD} or the voltage applied to the write bitline). That is, e.g., the write wordline voltage can be adjusted while monitoring the writability of the bitcell. When the monitoring of the writability of the bitcell indicates the bitcell can no longer be written to, the corresponding write wordline voltage will be directly proportional to the voltage used to write to the bitcell of the SRAM. The same can be said for, e.g., V_{DD} or the voltage applied to the write bitline. In some embodiments, all three voltages, e.g., write wordline/write bitline/supply voltages, can be used and adjusted in the monitoring the writability of the bitcell.

For example, at a starting write wordline voltage applied to the wordline of the bitcell of the SRAM, the monitoring of the writability of the bitcell indicates that the bitcell can be written to. Then, the write wordline voltage is decreased incrementally until the monitoring of the writability of the bitcell indicates the bitcell can no longer be written to. The specific write wordline voltage at this point will correlate to the actual voltage needed to successfully write to the bitcell. Of course, as discussed above, the supply voltage for the SRAM or the voltage for the write bitline for the bitcell could be substituted for the write wordline voltage.

The disclosed ring oscillator is configured to monitor the writability of the bitcell. The ring oscillator is formed from a set of test bitcells identical to bitcells used in an array of the SRAM. In general, the ring oscillator will propagate data through these test bitcells when the write wordline voltage is higher than a cutoff point, i.e., a point at which the write wordline voltage is too low for data to be written into the bitcell. Once the write wordline voltage drops below the cutoff point, the data will no longer be written to the bitcell and hence will not be able to propagate through the test bitcells of the ring oscillator. Data from an output of the ring oscillator is monitored at distinct different write wordline voltages that are separately applied to the test bitcells. Once data from the ring oscillator stops oscillating, the corresponding write wordline voltage value correlates to the minimum voltage needed to successfully write to the test bitcells, indicating the writability of the test bitcells.

The disclosed ring oscillator is configured to measure a write time of the bit cell. The frequency of oscillation of the data output from the ring oscillator directly correlates to a write time of the bitcell. As with the above-disclosed indication of writability of bitcells in the SRAM, the determined write time of the bitcell can also be fed back into the IC to control other parameters of the IC in which the test bitcells reside. For example, the overall operating voltage for the IC can be manipulated to be lowered, thereby saving power consumption of the IC, improving the speed at which the IC operates, or both based on the determined write time of the bitcells.

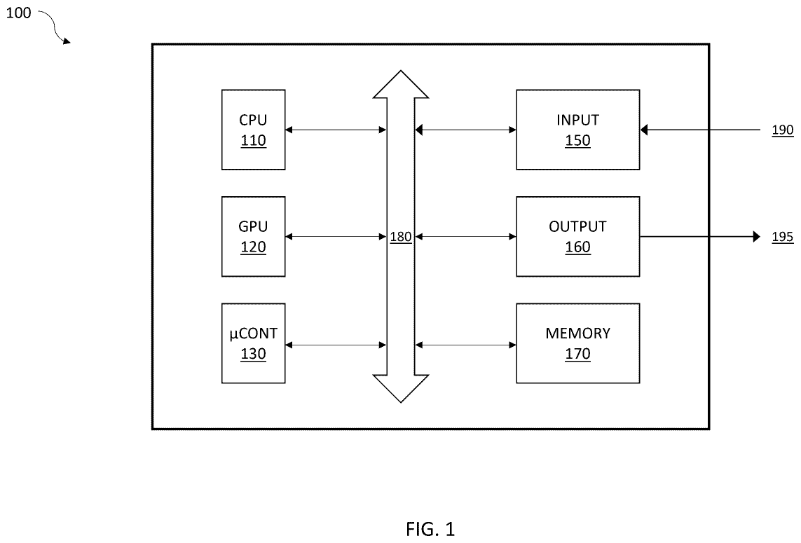

Referring to the drawings, specifically FIG. 1, a block diagram of an integrated circuit (IC) 100 constructed according to the principles of the disclosure is shown. IC 100 includes at least one CPU 110, at least one GPU 120, optionally at least one microcontroller 130, input circuitry 150, output circuitry 160, and memory 170. Of course, in some embodiments IC 100 can include more than one CPU 110, GPU 120, or microcontroller 130 or, in other embodiments, IC 100 could omit any of CPU 110, GPU 120, or microcontroller 130. As depicted in FIG. 1, in some embodiments, CPU 110, GPU 120, microcontroller 130, input circuitry 150, output circuitry 160, and memory 170 communicate with each other over bus 180. In some embodiments, additional busses between different processing units (e.g., CPU 110, GPU 120, and microcontroller 130) and between different processing units (e.g., CPU 110, GPU 120, and microcontroller 130), input circuitry 150, output circuitry 160, and memory 170 can be employed (not shown). Memory 170 can be comprised of differing types of volatile memories (e.g., dynamic random access (DRAM) memory, SRAM memory, etc.) and/or non-volatile memories (e.g., read-only memory (ROM), erasable programmable read-only memory (EPROM), electrically erasable programmable read-only memory (EEPROM), flash memory, etc.). In some embodiments of IC 100, memory 170 includes on-chip SRAM which includes a writability monitoring circuit constructed in accordance with the principles of the disclosure as described below. Also as depicted in FIG. 1, IC 100's input circuitry 150 accepts signals 190 externally provided to IC 100 and IC 100's output circuitry 160 provides signals 195 external to IC 100.

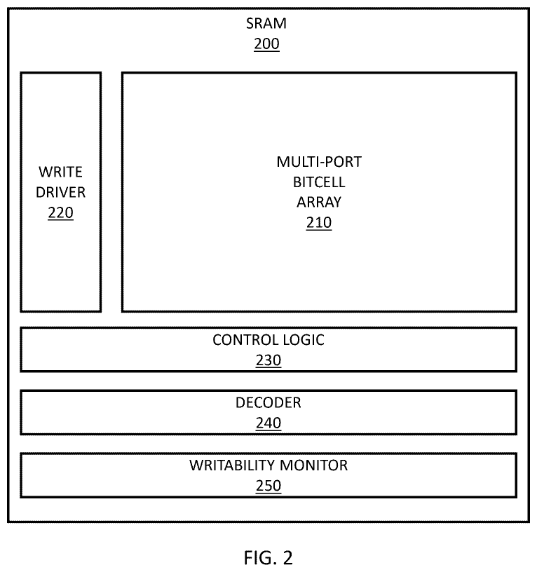

FIG. 2 illustrates a block diagram of an example of a static RAM (SRAM) 200 according to principles of the disclosure. SRAM 200 includes, inter alia, multi-port bitcell array 210, write driver 220, control logic 230, decoder 240, and writability monitor 250. Multi-port bitcell array is configured in sub-arrays, e.g., a number of identical m×n sub-arrays. Write driver 220, control logic 230, and decoder 240 are formed conventional as known in the art. Writability monitor 250 is described below. In some embodiments, SRAM 200 is part of memory 170 of FIG. 1.

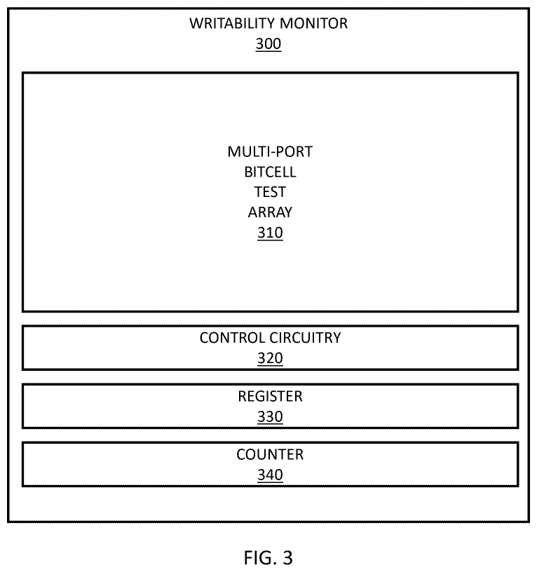

FIG. 3 illustrates a block diagram of an example of a writability monitor 300 according to principles of the disclosure. Writability monitor 300 is similar to writability monitor 250 of FIG. 2. Writability monitor 300 includes multi-port bitcell test array 310, control circuitry 320, register 330, and counter 340. Multi-port bitcell test array 310 includes an array of multi-port bitcells that is an exact copy of at least one of the m x n sub-arrays of the multi-port bitcell array, e.g., multi-port bitcell array 210 of FIG. 2, of the SRAM, e.g., SRAM 200 of FIG. 2. Multi-port bitcell test array 310 is configured as a ring oscillator which determines both a writability and write time of the multi-port bitcells in the multi-port bitcell test array, e.g., multi-port bitcell test array 310 as further described below. Control circuitry 320, inter alia, applies a voltage to the multi-port bitcells of multi-port bitcell test array 310.

As disclosed above, the voltage that control circuitry 320 applies to the multi-port bitcells of multi-port bitcell test array 310 can be, e.g., a write wordline voltage, a write bitline voltage, or a supply voltage (e.g., V_{DD}). In some embodiments, the voltage that control circuitry 320 applies to the multi-port bitcells of multi-port bitcell test array 310 is the write wordline voltage, write bitline voltage, and supply voltage concurrently. In order for writability monitor 300 to determine a writability of the multi-port bitcells in multi-port bitcell test array 310, control circuitry 320 varies the voltage it is applying to the multi-port bitcells in multi-port bitcell test array 310, be it the write wordline voltage, write bitline voltage, supply voltage, or all three voltages concurrently in a manner as disclosed above. Control circuitry 320 also monitors the output of the ring oscillator formed from the multi-port bitcells of multi-port bitcell array 310 for a given voltage applied to the multi-port bitcells of multi-port bitcell test array 310. If control circuitry 320 determines that the ring oscillator is oscillating, e.g., from an output of the ring oscillator, it will then vary the voltage it applies to the multi-port bitcells of multi-port bitcell test array 310 to a new voltage level. In some embodiments, this new voltage is a voltage lower than that previously applied. Control circuitry 320 again determines if the ring oscillator is oscillating at the new voltage applied to the multi-port bitcells of multi-port bitcell test array 310.

Control circuitry 320 will continue iteratively vary the voltage it applies to the multi-port bitcells of multi-port bitcell test array 310 until control circuitry 320 determines that the ring oscillator is not oscillating. At this point, the last voltage level that is applied to the multi-port bitcells of multi-port bitcell array 310 correlates to a voltage level that data can no longer successfully be written to the multi-port bitcells of multi-port bitcell array 310, indicating a writability of the multi-port bitcells of multiport bitcell test array 310. An indication of this writability voltage level will be stored in register 330. This indication of the writability of the multiport bitcells in multi-port bitcell array 310 will be transmitted from register 330 to another portion of the IC on which the SRAM resides. In some embodiments, the indication of the writability of the multi-port bitcells of multi-port bitcell array 310 is transmitted from register 330 to a microcontroller separate from the SRAM, e.g., microcontroller 130 of FIG. 1. Here, the writability indication will be used as disclosed above to either adjust other parameters of the IC (e.g., adjust an operating voltage of the IC) or be used to accurately predict electrical performance of the silicon for future designs for SRAMs using a same process technology.

Control circuitry 320 will also continuously monitor a frequency of data output from the ring oscillator formed from the multi-port bitcells of multi-port bitcell test array 310. The frequency of oscillation of the ring oscillator is measured when the ring oscillator is oscillating using a counter, e.g., counter 340. Thus, control circuitry 320 determines whether the ring oscillator, e.g., the ring oscillator formed from the multi-port bitcells of multi-port bitcell test array 310, is oscillating and when control circuitry 320 determines the ring oscillator is oscillating, control circuitry 320 causes counter 340 to count the frequency of oscillations. The frequency of oscillation of the ring oscillator formed from the multi-port bitcells of multi-port bitcell test array 310 measured by counter 340 correlates to the write time of the multi-port bitcells of multi-port bitcell test array 310.

As with the indication of writability of the multi-port bitcells of multi-port bitcell test array 310 being transmitted from register 330, this indication of write time of the multi-port bitcells of multi-port bitcell test array 310 is also transmitted from counter 340 to another portion of the IC on which the SRAM resides. In some embodiments, the indication of the write time of the multi-port bitcells of multi-port bitcell array 310 is transmitted from counter 340 to a microcontroller separate from the SRAM, e.g., microcontroller 130 of FIG. 1. Here, the write time indication will be used as disclosed above to either adjust other parameters of the IC (e.g., adjust an operating voltage of the IC) or be used accurately predict electrical performance of the silicon for future designs for SRAMs using a same process technology.

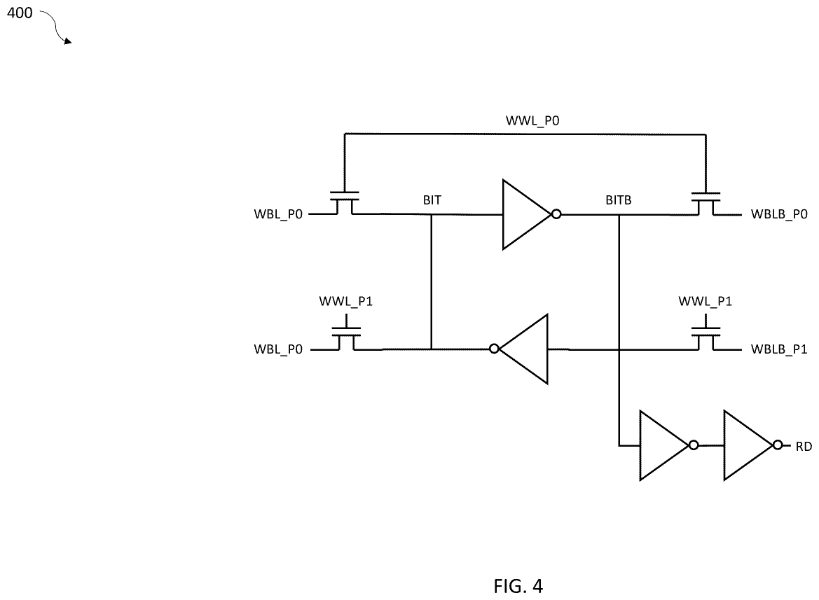

In principle, as disclosed above, the writability monitor forms a ring oscillator from multi-port bitcells, e.g., multi-port bitcells of multi-port bitcell test array 310. These multi-port bitcells and their corresponding ports are configured to be written to in a specific sequence. An enable signal triggers a first wordline of the ring oscillator and initiates a write operation. If the write operation is successfully completed, a next wordline in the sequence will be triggered. Successful write operations keep triggering wordlines in the specific sequence (e.g., as controlled by control circuitry 320 disclosed above) and oscillation continues while the enable signal remains asserted. Here, a write through operation is performed in which a read bitline state changes along with a change in bitcell data. A state of read bitlines is compared with expected data (write data) and if both are the same, the next word line will trigger. If the read data does not match with the write data, the next wordline will not trigger and oscillation will halt. Any wordline can be used as the ring oscillator output which connects to the counter, e.g., register 330 disclosed above. To check writability for the bitcells, the bitcell's read wordline is always on and only one read port is kept. In this bitcell configuration (e.g., write through), a change in the bitcell content will impact the read node. FIG. 4 illustrates a representative multi-port (2 port) bitcell 400 accordingly.

Various configurations of the multi-port bitcells in multi-port bitcell test array 310 will now be described.

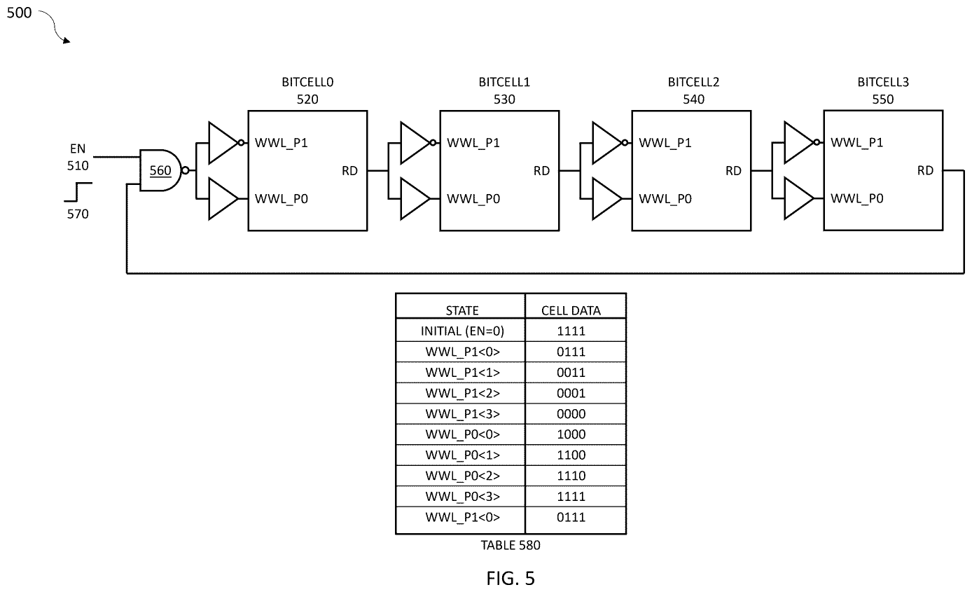

FIG. 5 illustrates a block diagram 500 of an example of a 4×1 two-port test bitcell array configured as a ring oscillator according to principles of the disclosure. The 4×1 two-port test bitcell array ring oscillator of block diagram 500 includes two-port bitcells 520, 530, 540, and 550 configured to form the ring oscillator. Each two-port bitcell 520, 530, 540, 550 has its own inverter network applied to its inputs. An output from a logic function is applied to the input of the first bitcell of the ring oscillator, e.g., bitcell0 520. In some embodiments the logic function is a NAND gate, e.g., NAND gate 560 as depicted in FIG. 5.

For simplicity, the bitlines are static in such a way that port 0 (P0) is always writing a data 1 and port 1 (P1) is always writing data 0. When an enable signal is low (e.g., EN=0) and applied to inverter network of bitcell0 520 of the ring oscillator (as depicted in waveform 570), all bitcells, e.g., bitcells 520, 530, 540, 550, are initialized to 1 as P0 wordlines are on. When the enable signal rises (e.g., EN=1 as depicted in waveform 570), WWL_P1 of bitcell0 520 goes high which writes data 0 into bitcell0 520. Subsequent write data changes to 0 in all bitcells and again P1 wordline makes it a 1. An output from an output of the last bitcell of the ring oscillator (e.g., output RD of bitcell3 550) is fed back to the logic function at the beginning of the ring oscillator. This operation goes on in a specific sequence as depicted in table 580 of FIG. 5 and oscillation continues while the enable signal remains high (EN=1).

As disclosed above, the frequency of oscillation correlates to the write time of the bitcells in the ring oscillator. The faster the write time, the higher the frequency. Moreover, if any bitcell is not writable, oscillation will stop at that bitcell.

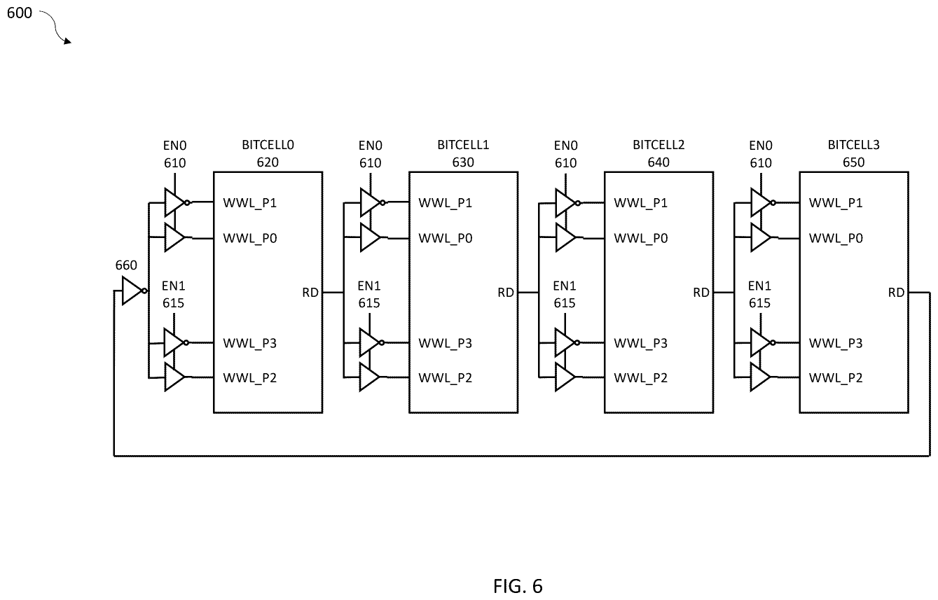

FIG. 6 illustrates a block diagram 600 of an example of a 4×1 four-port test bitcell array configured as a ring oscillator according to principles of the disclosure. The 4×1 four-port test bitcell array ring oscillator of block diagram 600 includes bitcells 620, 630, 640, and 650 configured to form the ring oscillator similar to the 4×1 two-port test bitcell array of FIG. 5. Each four-port bitcell 620, 630, 640, 650 has its own inverter network. However, different than the inverter networks of the two-port bitcells of the ring oscillator of FIG. 5, the invertor networks for the four-port bitcells of the ring oscillator of FIG. 6 have a separate enable signals, e.g., EN0 610 and EN1 615, each for different pairs of ports of the multi-port bitcells. In the example configuration of FIG. 6, enable signal EN0 is applied an invertor network to ports 0 and 1 of multi-port bitcells 620, 630, 640, 650 and enable signal EN1 is applied to another inventor network to ports 2 and 3 of multi-port 620, 630, 640, 650. Of course, other configurations of these enable signals are possible.

Enable signals EN0 and EN1 are generated similarly to enable 510 of FIG. 5. That is, enable signal EN0 is applied to a first logic function (not shown) as well as an inverted output from last bitcell3 650 (inverted by invertor 660) and enable signal EN1 is applied to a second logic function (not shown) as well as an inverted output from last bitcell3 650 (inverted by invertor 660). As with the logic function of FIG. 5 (e.g., logic function 560), the first and second logic functions (not shown) of FIG. 6 are NAND gates. Of course, in some embodiments, the logic functions could be different than a NAND gate.

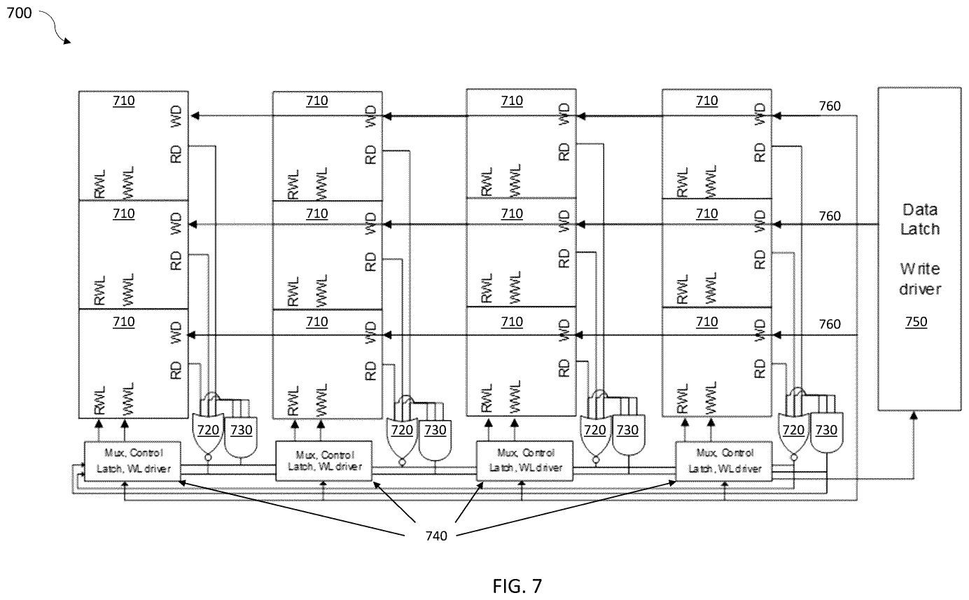

FIG. 7 illustrates a block diagram 700 of an example of a 4×1 two-port test bitcell array configured as a ring oscillator with control circuitry according to principles of the disclosure. The two-port test bitcell array of block diagram 700 includes two-port bitcells 710 arranged in a 4×1 array (as depicted in FIG. 7, each bitcell 710 has two separate RWL and WWL signals applied to them). An output of each two-port bitcell 710 (e.g., RD output) for each of the three columns of the 4×1 array are inputs to both NOR gate 720 and AND gate 730 for each column of the 4×1 array. Outputs from NOR gates 720 and AND gates 730 for each column of the 4×1 array are input into separate multiplexers (MUXs), control latches, and wordline (WL) drivers 740 for each column of the 4×1 array. Outputs from each of these separate MUX/control latch/WL drivers 740 are fed into data latch/write driver 750. An output from data latch/write driver 750 drives separate word lines (WD) 760 for each row in the 4×1 array.

NOR gates 720, AND gates 730, MUX/control latch/WL drivers 740, and data latch/write driver 750 comprise control circuitry for the 4×1 two-port test bitcell array of FIG. 7, similar to control circuitry 320 of FIG. 3. The output from the separate MUX/control latch/WL drivers 740 causes data latch/write drivers 740 to trigger a next wordline. As with the ring oscillators of FIGS. 5-6 disclosed above, the ring oscillator formed from the configuration of bitcells 710 also can determine both writability of bitcells 710 and a write time for bitcells 710 using the techniques disclosed above. That is, a frequency of the oscillations of the ring oscillator formed from bitcells 710 correlates to a write time for bitcells 710 and a voltage applied to bitcells 710 when bitcells 710 stop oscillating correlates to a writability of bitcells 710.

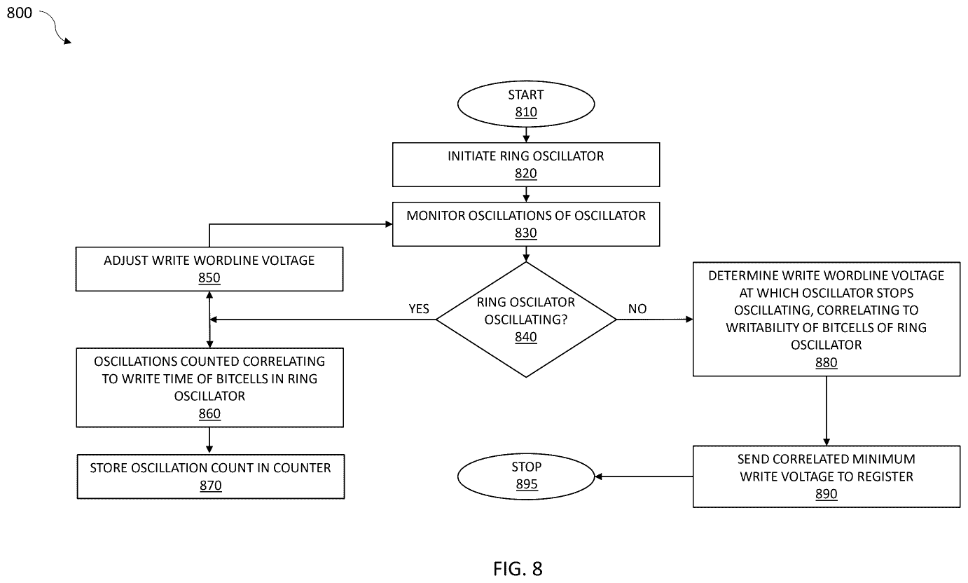

FIG. 8 illustrates a flow diagram of an example of a method 800 of determining writability and write time of multi-port test bitcells in an SRAM of an IC according to principles of the disclosure. At step 810, method 800 starts. At step 820, a ring oscillator is started or initiated. The ring oscillator is similar to the ring oscillators disclosed above and depicted in FIGS. 5-7. At step, 830, oscillations of the ring oscillator are monitored. At step 840, a determination is made as to whether the ring oscillator is oscillating. If, at step 840, it is determined that the ring oscillator is oscillating, method 800 proceeds to steps 850 and 860. At step 850, a write wordline voltage is adjusted. In some embodiments, the write wordline voltage is incrementally lowered. While method 800 indicates a write wordline voltage is adjusted, as disclosed above, a write bitline voltage or a supply voltage (to the bitcells) could be adjusted instead. In some embodiments all of a write wordline voltage, write bitline voltage, and a supply voltage are adjusted. The adjusted voltage is fed back to step 830 where oscillations of the ring oscillator is monitored.

At step 860 (the ring oscillator is oscillating as determined in step 840) the oscillations of the ring oscillator are counted and correlated to a write time of the bitcells. At step 870, the oscillation count is stored in a counter. If, at step 840, it is determined that the ring oscillator is not oscillating, method 800 proceeds to step 880. At step 880, a write wordline voltage (or, as disclosed above, a write bitline voltage or supply voltage, or all of a write wordline voltage, write bitline voltage, and supply voltage) at which the oscillator stops oscillating is determined where the determined voltage correlates to a writability of the bitcells of the ring oscillator. At step 890, the correlated minimum voltage (write wordline voltage, write bitline voltage, and/or supply voltage) is sent to a register. Method 800 stops at step 895. Thus, the write time of the bitcells can be determined while and before the writability of the bitcells is determined.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. A writability monitoring circuit in a static RAM (SRAM) of an integrated circuit (IC), comprising:
a register;
an array of multi-port test bitcells configured as a ring oscillator; and
control circuitry configured to:
apply a voltage to the array of multi-port test bitcells;
determine if the ring oscillator is oscillating;
when the ring oscillator is determined to be oscillating, adjust the voltage applied to the array of multi-port test bitcells; and
when the ring oscillator is determined to not be oscillating, determine a correlating minimum write voltage to successfully write to the array of multi-port test bitcells corresponding to a writability of the array of multi-port test bitcells and send the correlated minimum write voltage to the register.

2. The writability monitoring circuit as recited in claim 1, wherein the voltage applied to the array of multi-port test bitcells is selected from the group consisting of a write wordline voltage, a write bitline voltage, and a supply voltage.

3. The writability monitoring circuit as recited in claim 1, wherein the voltage applied to the array of multi-port test bitcells is a write wordline voltage, a write bitline voltage, and a supply voltage.

4. The writability monitoring circuit as recited in claim 1, wherein an enable signal is applied to the ring oscillator to start the ring oscillator.

5. The writability monitoring circuit as recited in claim 4, wherein:
the enable signal is applied to a first input of a logic gate and an output of the logic gate is applied to a first port of a first multi-port bitcell of the array of multi-port test bitcells and an inverse of the output of the logic gate is applied to a second port of the first multi-port bitcell of the array of multi-port test bitcells;
an output of the first multi-port bitcell is applied to a first port of a second multi-port bitcell of the array of multi-port test bitcells and an inverse of the output of the first multi-port bitcell is applied to a second port of the second multi-port bitcell of the array of multi-port test bitcells; and
an output of a last multi-port bitcell of the array of multi-port test bitcells is applied to a second input of the logic gate.

6. The writability monitoring circuit as recited in claim 5, wherein the logic gate is a NAND gate.

7. The writability monitoring circuit as recited in claim 5, further comprising combinatorial logic configured to combine outputs from different ports of the multi-port bitcells of the array of multi-port test bitcells.

8. The writability monitoring circuit as recited in claim 5, further comprising sequencing logic configured to sequence between different wordlines of the array of multi-port test bitcells.

9. The writability monitoring circuit as recited in claim 1, wherein a value of the correlated minimum write voltage stored in the register is sent to a controller of the IC.

10. The writability monitoring circuit as recited in claim 9, wherein the controller of the IC adjusts an overall operating voltage of the IC based on the correlated minimum write voltage.

11. The writability monitoring circuit as recited in claim 1, wherein the multi-port bitcells of the array of multi-port test bitcells are replicas of bitcells in an array of the SRAM.

12. The writability monitoring circuit as recited in claim 1, further comprising a counter, wherein in the counter counts oscillations of the ring oscillator to determine a frequency of the oscillations and the frequency of oscillations corresponding to a write time of the multi-port bitcells of the array of multi-port test bitcells.

13. The writability monitoring circuit as recited in claim 12, wherein a value of the counter is sent to a controller of the IC.

14. The writability monitoring circuit as recited in claim 13, wherein the controller of the IC adjusts an overall operating voltage of the IC based on the determined write time for the multi-port bitcells in the array of multi-port test bitcells.

15. A method of determining writability of multi-port test bitcells in a static RAM (SRAM) of an integrated circuit (IC), comprising:
initiating a ring oscillator formed from an array of the multi-port test bitcells in the SRAM;
monitoring oscillations of the ring oscillator for a voltage applied to the array of multi-port test bitcells;
when the ring oscillator is determined to be oscillating, adjusting the voltage applied to the array of multi-port test bitcells;
when the ring oscillator is determined to not be oscillating, determining a correlating minimum write voltage to successfully write to the array of multi-port test bitcells; and
sending the correlated minimum write voltage to a register of the SRAM.

16. The method as recited in claim 15, wherein the voltage applied to the array of multi-port test bitcells is selected from the group consisting of a write wordline voltage, a write bitline voltage, and a supply voltage.

17. The method as recited in claim 15, further comprising enabling the ring oscillator to start with an enabling signal.

18. The method as recited in claim 17, further comprising:
applying the enabling signal to a first input of a logic gate;
applying an output of the logic gate to a first port of a first multi-port bitcell of the array of multi-port test bitcells;
applying an inverse of the output of the logic gate to a second port of the first multi-port bitcell of the array of multi-port test bitcells;
applying an output of the first multi-port bitcell to a first port of a second multi-port bitcell of the array of multi-port test bitcells;
applying an inverse of the output of the first multi-port bitcell to a second port of the second multi-port bitcell of the array of multi-port bitcells; and
applying an output of a last multi-port bitcell of the array of multi-port test bitcells to a second input of the logic gate.

19. The method as recited in claim 15, further comprising combining outputs from different ports of the multi-port bitcells of the array of multi-port test bitcells.

20. The method as recited in claim 15, further comprising sequencing between different wordlines of the array of multi-port test bitcells.

21. The method as recited in claim 15, further comprising sending the correlated minimum write voltage from the register of the SRAM to a controller of the IC.

22. The method as recited in claim 21, further comprising adjusting an overall operating voltage of the IC based on the correlated minimum write voltage.

23. The method as recited in claim 15, further comprising altering a future design of an SRAM based on the correlated minimum write voltage.

24. The method as recited in claim 15, further comprising counting oscillations of the ring oscillator to determine a frequency of the oscillations, the frequency of oscillations corresponding to a write time of the multi-port bitcells of the array of multi-port bitcell test bitcells.

25. The method as recited in claim 24, further comprising sending a value of the counted oscillations to a controller of the IC.

26. The method as cited in claim 25, further comprising adjusting an overall operating voltage of the IC based on the write time for the multi-port bitcells in the array of multi-port test bitcells corresponding to the determined frequency of oscillations of the ring oscillator.

27. A static RAM (SRAM) of an integrated circuit (IC), comprising:
an array of multi-port bitcells;
write drivers for the array of multi-port bitcells;
a decoder for the array of multi-port bitcells;
control logic for the array of multi-port bitcells; and
a writability monitoring circuit, the writability monitoring circuit comprising:
a register;
an array of multi-port test bitcells configured as a ring oscillator; and
control circuitry configured to:
apply a voltage to the array of multi-port test bitcells;
determine if the ring oscillator is oscillating;
when the ring oscillator is determined to be oscillating, adjust the voltage applied to the array of multi-port test bitcells; and
when the ring oscillator is determined to not be oscillating, determine a correlating minimum write voltage to successfully write to the array of multi-port test bitcells and send the correlated minimum write voltage to the register.

28. The SRAM as recited in claim 27, wherein the voltage applied to the array of multi-port test bitcells is selected from the group consisting of a write wordline voltage, a write bitline voltage, and a supply voltage.

29. The SRAM as recited in claim 27, wherein an enable signal is applied to the ring oscillator to start the ring oscillator.

30. The SRAM as recited in claim 27, wherein a value of the correlated minimum write voltage stored in the register is sent to a controller of the IC.

31. The SRAM as recited in claim 30, wherein the controller of the IC adjusts an overall operating voltage of the IC based on the correlated minimum write voltage.

32. The SRAM as recited in claim 27, wherein the multi-port bitcells of the array of multi-port test bitcells are replicas of the multi-port bitcells of the SRAM array of multi-port bitcells.

33. The SRAM as recited in claim 27, further comprising a counter, wherein in the counter counts oscillations of the ring oscillator to determine a frequency of the oscillations and the frequency of oscillations corresponding to a write time of the multi-port bitcells of the array of multi-port test bitcells.

34. The SRAM as recited in claim 33, wherein a value of the counter is sent to a controller of the IC.

35. The SRAM as recited in claim 34, wherein the controller of the IC adjusts an overall operating voltage of the IC based on the write time for the multi-port bitcells in the array of multi-port test bitcells corresponding to the determined frequency of oscillations of the ring oscillator.

36. A library of circuit designs, comprising:
a design for a writability monitoring circuit in a static RAM (SRAM) of an integrated circuit (IC), wherein the writability monitoring circuit includes:
a register;
an array of multi-port test bitcells configured as a ring oscillator; and
control circuitry configured to:
apply a voltage to the array of multi-port test bitcells;
determine if the ring oscillator is oscillating;
when the ring oscillator is determined to be oscillating, adjust the voltage applied to the array of multi-port test bitcells; and
when the ring oscillator is determined to not be oscillating, determine a correlating minimum write voltage to successfully write to the array of multi-port test bitcells and send the correlated minimum write voltage to the register.

37. A writability monitoring circuit in a static RAM (SRAM) of an integrated circuit (IC), comprising:
a register;
an array of test bitcells configured as a ring oscillator; and
control circuitry configured to determine a correlating minimum write voltage to successfully write to the array of test bitcells and send the correlated minimum write voltage to the register.

38. The writability monitoring circuit as recited in claim 37, wherein a controller of the IC adjusts an overall operating voltage of the IC based on the correlated minimum write voltage sent to the controller.
